(19) United States
(12) Patent Application Publication
(10) Pub. No.: US 2021/0296848 A1
(43) Pub. Date: Sep. 23, 2021

(54) LASER DIAGNOSTICS APPARATUS

(71) Applicant: ARRIS Enterprises LLC, Suwanee, GA (US)

(72) Inventor: Hector E. Sanchez, Monterrey (MX)

(21) Appl. No.: 17/204,730

(22) Filed: Mar. 17, 2021

Related U.S. Application Data
(60) Provisional application No. 62/990,700, filed on Mar. 17, 2020.
(60) Provisional application No. 63/074,326, filed on Sep. 3, 2020.

(51) Int. Cl. H01S 5/00; G01J 3/18; H01S 5/02251

(52) U.S. Cl. CPC H01S 5/0014; H01S 5/02251; G01J 3/1895

(57) ABSTRACT

A multimode laser that generates laser emissions that are transmitted into an optical coupling then an optical filter to test for failures or faults within that optical filter is provided herein. Multimode lasers generate emissions which many different modes are present in the gain curve. Due to this, typical multi-mode laser failure-cases can be observed in the output frequency signal of laser emissions passing through an optical component. By using a spectrometer to analyze the exiting laser wavelengths, specific failure-cases of the optical component can be identified and related to root causes.

### CROSS REFERENCE TO RELATED APPLICATIONS

This application claims benefit of U.S. Provisional Patent Application No. 62/990,700, entitled “LASER DIAGNOSTICS APPARATUS,” by Hector E. Sanchez, filed Mar. 17, 2020 and U.S. Provisional Patent Application No. 63/074,326, entitled “LASER DIAGNOSTICS APPARATUS,” by Hector E. Sanchez, filed Sep. 3, 2020, which are both hereby incorporated by reference.

### BACKGROUND

The present disclosure generally relates to testing of optical components, and, more specifically, to systems and methods that diagnose specific failure modes within an optical component such as a Fiber-Bragg grating.

A Fiber-Bragg grating (FBG) is a type of distributed reflector constructed in a short segment of optical fiber that reflects particular wavelengths of light and transmits all others. This is achieved by creating a periodic variation in the refractive index of the fiber core, which generates a wavelength-specific dielectric mirror. A Fiber-Bragg grating can therefore be used as an inline optical filter to block certain wavelengths, or as a wavelength-specific reflector.

FBG devices are used in numerous applications, including operating as distributed pass-band filters/notch filters in fiber optic communication systems, as well as being used in multiplexers and demultiplexers in such systems. In recent years, FBG's have been used in other applications, such as their inclusion as a component in high-power fiber lasers where the FBG can be used as the high reflector and output coupler to form the laser cavity, so as to provide wavelength stabilization for semiconductor pump lasers. Maturation and improvement of the FBG technology has even allowed some applications to function without more traditional Thermo-Electric Cooling (TEC) technology, thus allowing the possibility of increasing the affordability of air-cooled pump lasers for most applications.

Even though the performance of an FBG distributed filter is very non-dependent on temperature, its humidity and shock dependencies remain important reliability factors that can distraught the laser output. It is thus very important for a component engineer to locate and isolate failure modes related to the laser packaging before the application is realized to the public.

### SUMMARY

The present invention provides a system for quickly and efficiently testing optical components by introducing multimode laser emissions into the components, then observing the wavelengths of the laser light passing through and exiting the components. Based on the variation between the input and output wavelengths, defects or failure conditions within the component are identified.

A first embodiment of the disclosure may comprise a laser diagnostic apparatus including a multimode laser diode, an optical coupling having a cleaved tip, an optical medium containing an optical filter acting as at least one of a distributed filter and a selectively reflective mirror, and a spectrum sensor that detects emissions from the multimode laser diode after the emissions have passed through the optical filter.

A second embodiment of the disclosure may comprise an apparatus for discovering fault states within an optical filter comprising a multimode laser diode, an optical coupling having a cleaved tip, an optical medium containing an optical filter operating as at least one of a distributed filter and a selectively reflective mirror, a tunable optical nudge filter arranged to receive emissions from the multimode laser diode after the emissions have passed through the optical filter, and a photodiode arranged to receive the emissions from the multimode laser diode after the emissions have passed through the tunable optical filter.

A third embodiment of the disclosure may comprise a method for determining defects within a fiber Bragg grating comprising the steps of providing a multimode laser cavity, causing emissions from the multimode laser cavity to enter an end of a fiber coupling, causing the emissions from the multimode laser cavity to pass through a fiber Bragg grating and to a spectrum sensing device, and detecting defects within the Fiber-Bragg based on an output of the spectrum sensing device.

### BRIEF DESCRIPTION OF THE DRAWINGS

FIG. 1 is a functional FBG laser scheme.

FIG. 2 is a block diagram of FBG laser scheme along with the respective spectral response at each stage.

FIG. 3 is a sensing scheme where output is observed by using a spectrometer.

FIG. 4 is a sensing scheme that uses a tunable optical nudge filter and a photodiode to analyze emission profile.

### DETAILED DESCRIPTION

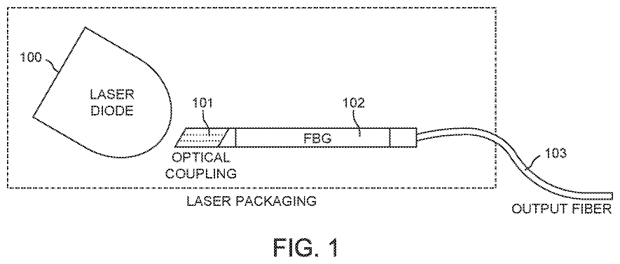

Referring now to FIGS. 1-4 that will be discussed together, there is shown a laser diagnostic apparatus used to diagnose specific failure modes in optical bandpass filters such as Fiber-Bragg gratings. As seen in FIG. 1, a laser diode (100) introduces laser signals into an optical medium that has an FBG (102) by way of an optical coupling having a cleaved tip (101). The FBG (102) can function as a distributed filter or can act as a selectively reflective mirror, in which case the filter is considered intra-cavity. Alternatively, it can be an extra-cavity configuration. The laser signals passing through the FBG (102) travel out of the laser packaging by way of an output fiber (103).

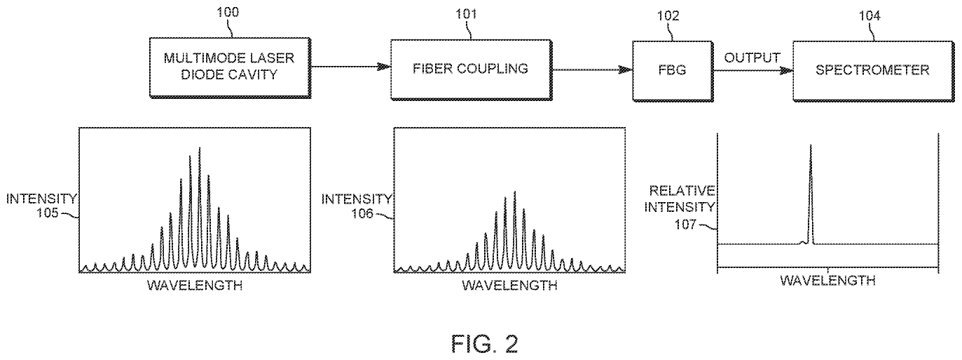

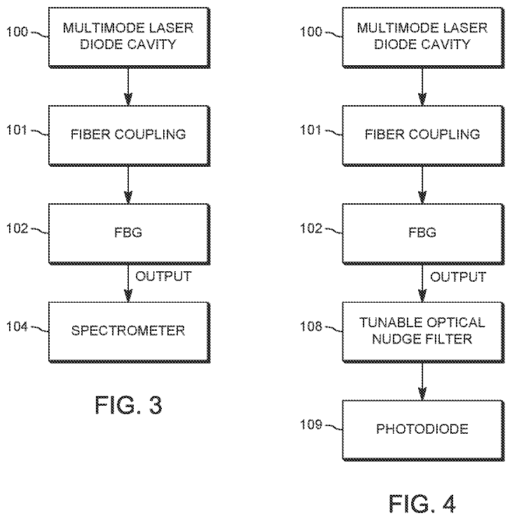

The frequency content of the output signal is a product of each stage of the laser signal generation, transmission, and filtering. These stages are shown in FIG. 2. The signal is structurally different between all the stages of transduction. By placing a spectrum sensing device at the output (FIG. 3, 104; FIG. 4, 108, 109) one can interpret the output laser signal thereby allowing failure modes to be categorized iteratively.

In FIG. 2, it is seen that a multimode laser (100) generates light emissions along a plurality of wavelengths, with different magnitudes of intensity per wavelength (105). The laser emissions enter a test package through the fiber coupling (101), and in some embodiments the fiber coupling has a cleaved tip (see FIG. 1, 101). Upon entering the fiber coupling (101), the amplitude of the emissions is reduced (106) due to the inherent properties of optical fibers. The laser emissions travel through the fiber coupling (101) and in to the FBG (102) where it is filtered or refracted, then out to a spectrum sensing device. In some embodiments, the spectrum sensing device can be a spectrometer (104). In other embodiments, the spectrum sensing device is a tunable optical nudge filter (108) coupled with a photodiode (109).

The wavelengths of light passing through the FBG (101) is detected by the spectrum sensing device (104 or 108, 109). The detected wavelength or wavelengths of the laser emissions are analyzed according to their relative intensity (107) to determine if there is a failure or fault within the FBG (102). A failure would be a wavelength outside of an acceptable range being detected, no light being detected, incorrect intensity of the light being detected, or any other combination of wavelength or intensity deviations that are outside of acceptable parameters.

FIG. 3 shows a multimode laser (100) that introduces light emissions into a fiber coupling with a cleaved tip (101) that is optically connected to an FBG (102), where the FBG (102) is undergoing testing, and an output path for the laser emissions terminating in a spectrometer (104). The output path is typically an output fiber (103), but in some embodiments can be the spectrometer (104) itself

In an exemplary embodiment, a method is provided for testing FBG components (102). It should be noted that other types of optical filter such as multi or single mode bandpass filters can be tested using the present invention. The method begins with providing a multimode laser cavity (100) and attaching the multimode laser cavity to a fiber coupling (101). Alternatively, the method begins with causing the laser emissions of a multimode laser (100) to enter an end of a fiber coupling (101) if the laser (100) and fiber coupling (101) are not physically attached. The next step of the method is to cause or provide for the transmission of the laser emissions from the fiber coupling (101) into an FBG (102). Then the method calls for providing a means, such as an output fiber (103) for the light emissions to travel from the FBG (102) to a spectrometer (104). The wavelengths of light emitted from the FBG (102) are detected by the spectrometer (104). Alternatively, the light emissions could travel directly from the FBG (102) to the spectrometer (104) without first having to pass through an output fiber (103).

After detection by the spectrometer (104), the wavelengths are analyzed for faults or failures. This analysis can occur through user observation of the spectrometer readings, or by way of computer analysis. The fault and failure analysis comprises taking the detected laser emission readings and comparing them to known or expected emissions. If deviations occur, the type of deviation can be analyzed to determine the exact nature of the fault or failure.

In embodiments where mass manufacturing occurs, and testing of many FBG (102) or other optical components must occur, faster response time spectrometers (104) can be used and improved means for swapping FBGs (102) or other input devices under test can be used to speed up the process.

FIG. 4 shows another embodiment of the present invention. This embodiment consists of a multimode laser (100) that introduces light emissions into a fiber coupling with a cleaved tip (101) that is optically connected to an FBG (102), where the FBG (102) is undergoing testing, and an output path for the laser emissions that guide the emissions through a tunable optical nudge filter (108) and in to a photodiode (109). The output path for this embodiment may or may not comprise an output fiber (103) that connects the FBG (102) to the tunable optical nudge filter (108).

In an exemplary embodiment, a method is provided for testing FBG components (102) using the configuration illustrated in FIG. 4. It should be noted that other types of optical filter such as multi or single mode bandpass filters can also be tested using this embodiment. The method begins with providing a multimode laser cavity (100) and attaching the multimode laser cavity to a fiber coupling (101). Alternatively, the method begins with causing the laser emissions of a multimode laser (100) to enter an end of a fiber coupling (101) if the laser (100) and fiber coupling (101) are not physically attached. The next step of the method is to cause or provide for the transmission of the laser emissions from the fiber coupling (101) into an FBG (102). Then the method calls for providing a means, such as an output fiber (103) for the light emissions to travel from the FBG (102) to a tunable optical nudge filter (108). Then, the invention causes wavelengths to pass from the tunable optical nudge filter (108) to the photodiode (109).

In this embodiment, the output from the FBG (102) is input into the photodiode (109) and only the power output is analyzed. The complete signal profile is obtained by performing a spectrum sweep. Spectrum output from the multimode laser cavity (100) is not typically very narrow in wavelength, and thus, its features can be elucidated by a relatively coarse filter. Tunable optical nudge filters (108) as used with the present invention include thermally tunable FBG's, tunable resonators, acousto-optic filters or liquid crystal modulators.

The power output is then analyzed for faults or failures. This analysis can occur through user observation of the power readings, or automatically by way of computer analysis. The fault and failure analysis comprises taking the power readings and comparing them to known or expected power levels. If deviations occur, the type of deviation can be analyzed to determine the exact nature of the fault or failure. It should be noted that this embodiment can still perform wavelength analysis by obtaining a signal profile through a spectrum sweep. When done, the signal wavelength information can be analyzed to determine faults or failures.

Unless otherwise defined, all technical and scientific terms used herein have the same meaning as commonly understood by one of ordinary skill in the art to which this invention belongs. Although methods and materials similar to or equivalent to those described herein can be used in the practice or testing of the symmetrical measuring tool, suitable methods and materials are described above. All publications, patent applications, patents, and other references mentioned herein are incorporated by reference in their entirety to the extent allowed by applicable law and regulations. The symmetrical measuring tool may be embodied in other specific forms without departing from the spirit or essential attributes thereof, and it is therefore desired that the present embodiment be considered in all respects as illustrative and not restrictive. Any headings utilized within the description are for convenience only and have no legal or limiting effect.

I claim:

1. A laser diagnostic apparatus comprising:
a multimode laser diode;
an optical coupling having a cleaved tip;
an optical medium containing an optical filter acting as at least one of a distributed filter and a selectively reflective mirror; and
a spectrum sensor that detects emissions from the multimode laser diode after the emissions have passed through the optical filter.

2. The laser diagnostic apparatus of claim 1 where the multimode laser diode is configured to generate light emissions along a plurality of wavelengths, with varying power intensities along said wavelengths.

3. The laser diagnostic apparatus of claim 1 wherein the optical coupling is a fiber optic cable.

4. The laser diagnostic apparatus of claim 1 wherein the optical filter is a fiber Bragg grating.

5. The laser diagnostic apparatus of claim 1 wherein the spectrum sensing device is a spectrometer.

6. The laser diagnostic apparatus of claim 1 further comprising an output fiber connected to the optical filter and the spectrum sensing device.

7. The laser diagnostic apparatus of claim 1 including a display device that displays wavelengths to a user.

8. An apparatus for discovering fault states within an optical filter comprising:
a multimode laser diode;
an optical coupling having a cleaved tip;
an optical medium containing an optical filter operating as at least one of a distributed filter and a selectively reflective mirror;
a tunable optical nudge filter arranged to receive emissions from the multimode laser diode after the emissions have passed through the optical filter; and
a photodiode arranged to receive the emissions from the multimode laser diode after the emissions have passed through the tunable optical filter.

9. The laser diagnostic apparatus of claim 8 where the multimode laser diode is configured to generate light emissions along a plurality of wavelengths, with varying power intensities along said wavelengths.

10. The laser diagnostic apparatus of claim 8wherein the optical coupling is a fiber optic cable.

11. The laser diagnostic apparatus of claim 8 wherein the optical filter is a fiber Bragg grating.

12. The laser diagnostic apparatus of claim 8 wherein the photodiode is designed detect power output readings of the emissions from the multimode laser.

13. The laser diagnostic apparatus of claim 8 further comprising an output fiber connected to the optical filter and the tunable optical nudge filter.

14. The laser diagnostic apparatus of claim 1 including a display device that displays power output readings to a user.

15. A method for determining defects within a fiber Bragg grating comprising:
providing a multimode laser cavity;
causing emissions from the multimode laser cavity to enter an end of a fiber coupling;
causing the emissions from the multimode laser cavity to pass through a fiber Bragg grating and to a spectrum sensing device; and
detecting defects within the Fiber-Bragg based on an output of the spectrum sensing device.

16. The method of claim 15 further comprising causing one end of the fiber coupling to be cleaved.

17. The method of claim 15 further comprising providing an output fiber that transmits the emissions from the multimode laser cavity to the spectrum sensing device.

18. The method of claim 15 further comprising providing a spectrometer as the spectrum sensing device.

19. The method of claim 15 further comprising providing a tunable optical nudge filter and a photodiode as the spectrum sensing device.

20. The method of claim 15 including comparing detected emissions from the multimode laser cavity to acceptable parameters of at least one of received wavelengths and power levels.
